(19) United States
(12) Patent Application Publication
(10) Pub. No.: US 2007/0227440 A1
(43) Pub. Date: Oct. 4, 2007

(54) ARSENIC DOPANTS FOR PULLING OF SILICON SINGLE CRYSTAL, PROCESS FOR PRODUCING THEREOF AND PROCESS FOR PRODUCING SILICON SINGLE CRYSTAL USING THEREOF

(75) Inventor: Kazuhiko KASHIMA, Tokyo (JP)

Correspondence Address: FOLEY AND LARDNER LLP;SUITE 500, 3000 K STREET NW, WASHINGTON, DC, 20007, US

(73) Assignee: TOSHIBA CERAMICS CO., LTD.

(21) Appl. No.: 11/756,976

(22) Filed: Jun. 1, 2007

Related U.S. Application Data
(62) Division of application No. 11/085,044, filed on Mar. 22, 2005.

(30) Foreign Application Priority Data
Mar. 29, 2004 (JP) 2004-096208
Jan. 14, 2005 (JP) 2005-007335

(51) Int. Cl. C30B 23/00

(52) U.S. Cl. 117/19

(57) ABSTRACT

Silicon single crystal is pulled by the Czochralski method, using an As dopant comprising a mixed sintered compact of arsenic and silicon, the molar ratio of silicon being not smaller than 35% and not greater than 55% relative to arsenic.

### CROSS-REFERENCE TO RELATED APPLICATIONS

This application is based upon and claims the benefit of priority from the prior Japanese Patent Application No. 2004-96208, filed on Mar. 29, 2004 and No. 2005-007335, filed on Jan. 14, 2005, the entire contents of which are incorporated herein by reference.

### BACKGROUND OF THE INVENTION

1. Field of the Invention

The present invention relates to an arsenic dopant for pulling of silicon single crystal to be used for doping when growing silicon single crystal by means of the Czochralski method, a process for producing thereof and a process for producing silicon single crystal using thereof.

2. Description of the Related Art

When producing silicon single crystal by means of the Czochralski method, the resistivity is controlled to a desired level according to the specification and the object of the production. The resistivity (specific resistance) is controlled by adding a dopant such as phosphorus (P), antimony (Sb) or arsenic (As) to silicon melt to a small ratio at the growing the silicon single crystal.

Of the above listed dopants, phosphorus shows a relatively high melting point and it is easy to control the resistance thereof. On the other hand, evaporated phosphorus in the furnace can be oxidized and ignited by air to give rise to a fire. Thus, the use of a large amount of phosphorus for reducing the resistivity of silicon single crystal is inevitably limited. For this reason, antimony and arsenic are being popularly used as dopants for producing low resistivity silicon single crystal. Antimony shows a low solid solubility relative to silicon. Thus, the use of antimony for reducing the resistivity of silicon single crystal is also inevitably limited.

Arsenic shows a very high solid solubility relative to silicon and hence is being popularly used as dopant. The melting point and the sublimation point of arsenic are 816° C. and 615° C. respectively, which are very low relative to the melting point of silicon, which is 1,420° C. so that it can be evaporated in a single crystal pulling system, which is held to a very high temperature. Therefore, it is difficult to control the operation of adding the dopant to a high concentration. Additionally, when arsenic is used alone as dopant, it can give rise to highly toxic arsenic oxide (III) (As₂O₃) in air, which is very hazardous to the attending workers and can highly possibly harm the health of the workers.

As an attempt to solve the problems, a dopant prepared by coating a proper arsenic dopant with layers of an arsenic compound, silicon and a silicon compound has been proposed (Jpn. Pat. Appln. Laid-Open Publication No. 2000-319087: to be referred to as Patent Document 1 hereinafter).

Besides, although not for pulling of silicon single crystal, an arsenic diffusion medicine for diffusing arsenic in a semiconductor substrate by heat treatment that contains silicon arsenide (SiAs), silicon and inorganic filler at a ratio by weight of 1:1˜200:0˜200 has been proposed (Jpn. Pat. Appln. Laid-Open Publication No. 2-143421: to be referred to as Patent Document 2 hereinafter).

However, a coated arsenic dopant as described in Patent Document 1 has a drawback that the arsenic atoms can be exposed to air to give off highly toxic arsenic oxide (III) (As₂O₃), which is very hazardous, once the coat is destroyed, if partly. Additionally, when the dopant is dissolved into raw material silicon melt, the coat of the dopant can easily dissolve and become lost while it is floating on the surface of the melt. Then, arsenic is exposed alone to air in the pulling system, which is held to a very high temperature, so that it is not dissolved sufficiently into the raw material silicon melt but sublimated. Thus, it is difficult to sufficiently reduce the resistivity of silicon single crystal.

While, on the other hand, an arsenic dopant as described in Patent Document 2 is not accompanied by the risk of giving off arsenic oxide (III), it contains silicon to a large extent and hence it is difficult to sufficiently reduce the resistivity of silicon single crystal by using such an arsenic dopant.

Therefore, there has been in recent years and still is a strong demand for an arsenic dopant to be used for pulling of silicon single crystal that is safe and can be used to control the process of reducing the resistance of silicon single crystal with ease. Also, there has been in recent years and still is a strong demand for pulled silicon single crystal showing a reduced intra-planar resistivity in radial directions.

### BRIEF SUMMARY OF THE INVENTION

According to embodiments of the present invention, it is an object of the present invention to provide an arsenic dopant to be used for pulling of silicon single crystal that can efficiently dope silicon single crystal with arsenic to remarkably reduce the resistivity of silicon single crystal and the intra-planar resistance of silicon single crystal in radial directions, a process for producing such an arsenic dopant and a process for producing silicon single crystal, using such an arsenic dopant.

The present invention may provide an As dopant for pulling of silicon single crystal, comprising: a mixed sintered compact of arsenic and silicon (1), the molar ratio of silicon being not smaller than 35% and not greater than 55% relative to arsenic (2).

The present invention may provide a process for producing an As dopant for pulling of silicon single crystal which comprises: (1) mixing granular, needle-like or powdery arsenic and silicon to a molar ratio of silicon not smaller than 35% and not greater than 55% relative to arsenic; and (2) sintering the mixture in vacuum at a temperature not lower than 816° C. and not higher than 944° C.

The present invention may provide a process for producing a silicon single crystal which comprises: (1) a step of filling a crucible with raw material silicon, melting the silicon to form raw material silicon melt; (2) a step of introducing an As dopant comprising a mixed sintered compact of arsenic and silicon, the molar ratio of silicon being not smaller than 35% and not greater than 55% relative to arsenic, into the raw material silicon melt and melting the As dopant; and (3) a step of growing the silicon single crystal by allowing seed crystal of silicon single crystal to contact the raw material silicon melt containing the dissolved As dopant.

### BRIEF DESCRIPTION OF THE DRAWINGS

Further objects and advantages of the invention can be more fully understood from the following detailed description taken in conjunction with the accompanying drawings, in which:

FIG. 1 is a graph schematically illustrating the results of observation of an embodiment of As dopant for pulling of silicon single crystal according to the invention by means of an X-ray diffractometer (XRD); and

FIG. 2 is a graph schematically illustrating the phases of an Si—As system.

### DETAILED DESCRIPTION OF THE INVENTION

Now, the present invention will be described in greater detail by way of a preferred embodiment of the invention.

An As dopant for pulling of silicon single crystal according to the invention comprises a mixed sintered compact of arsenic and silicon. It is desirable that the molar ratio, or the ratio of the number of mols of silicon to that of arsenic contained in the mixed sintered compact having a predetermined mass is not smaller than 35% and not greater than 55%.

If the molar ratio of silicon is smaller than 35% relative to arsenic, the arsenic component of the sintered compact of SiAS₂ can partly become sintered residue, which is then sublimated in the process of pulling of silicon single crystal to produce highly harmful arsenic oxide (III). If, on the other hand, the molar ratio of silicon exceeds 55% relative to arsenic, the sintered SiAs₂ can become short of As to limit the productivity of low resistance substrates. When an arsenic compound is crushed, trying to turn it to granules in order to introduce it into the raw material silicon melt as dopant, it is not turned to granules but is to laminates that resemble mica, which adhere to the dopant feeding jig to make it highly difficult to introduce it into the raw material silicon melt.

Preferably, the molar ratio of silicon is not smaller than 45% and not greater than 50% relative to arsenic.

An As dopant for pulling of silicon single crystal as described above can be produced by sintering a mixture of granular, needle-like or powdery arsenic and silicon to make silicon show a molar ratio not smaller than 35% and not greater than 55% relative to arsenic in vacuum at a temperature not lower than 816° C. and not higher than 944° C.

It is desirable that the sintering temperature is not lower than 816° C. and not higher than 944° C.

If the sintering temperature is lower than 816° C., arsenic is not liquefied but remains as solid so that the operation of sintering arsenic with silicon does not progress satisfactorily and arsenic undesirably remains as residue, if partly. If, on the other hand, the sintering temperature exceeds 944° C., the Si—As bond can become broken to allow arsenic to remain as residue, if partly.

The resistivity of silicon single crystal that is grown by the Czochralski method can be reduced remarkably by pulling of silicon single crystal by means of the Czochralski method, using an As dopant for pulling of silicon single crystal according to the invention.

Furthermore, the resistivity of silicon single crystal grown by the Czochralski method can be remarkably reduced more safely and more efficiently by means of a process for producing silicon single crystal using an As dopant according to the invention, the process comprising a step of filling a crucible with raw material silicon, melting the silicon to form raw material silicon melt, a step of introducing an As dopant comprising a mixed sintered compact of arsenic and silicon, the molar ratio of silicon being not smaller than 35% and not greater than 55% relative to arsenic, into the raw material silicon melt and melting the As dopant and a step of growing the silicon single crystal by allowing seed crystal of silicon single crystal to contact the raw material silicon melt containing the dissolved As dopant.

For a process of producing silicon single crystal according to the invention, an As dopant according to the invention, which is an As dopant comprising a mixed sintered compact of arsenic and silicon, the molar ratio of silicon being not smaller than 35% and not greater than 55% relative to arsenic.

As described above, an As dopant according to the invention is a mixed sintered compact in which all the arsenic forms a compound with silicon. Thus, when it is introduced into raw material silicon melt, sublimation of arsenic is suppressed even in the high temperature range in the system for pulling of silicon single crystal until it gets to the melt. Furthermore, if the mixed sintered compact floats on the surface of the raw material silicon melt before it is molten in the melt (arsenic and the arsenic compound have a density higher than that of silicon melt so that it is presumed that sublimated gaseous arsenic is floating if arsenic is floating alone on the surface of silicon melt), sublimation of arsenic that can take place after decomposition of the arsenic compound is minimized.

Preferably, the As dopant is introduced into the crucible after melting the raw material silicon filled in the crucible so as to produce melt.

If the As dopant is introduced into the crucible simultaneously with the raw material silicon, arsenic may not be molten into the silicon melt and hence silicon single crystal may not be sufficiently doped with arsenic because it takes a long time for the raw material silicon to be molten at high temperature and the As dopant can be sublimated in the course of time.

Therefore, it is preferable that an As dopant according to invention is introduced into the crucible after melting the raw material silicon filled in the crucible so as to produce melt. Then, decomposition of the arsenic compound and subsequent sublimation of arsenic can be suppressed during the operation of introducing the As dopant so that silicon single crystal can be efficiently doped with arsenic according to the invention.

### EXAMPLES

Powdery silicon (atomic weight: 28.09) was added to 100 g of granular arsenic (atomic weight: 79.92) with a grain diameter of 2 mm to molar ratios of 0% (Comparative Example 1), 25% (9.4 g: Comparative Example 2), 35% (13.1 g: Example 1), 45% (16.9 g: Example 2), 50% (18.75 g: Example 3), 55% (20.6 g: Example 4), 60% (22.5 g: Comparative Example 3) and the mixtures were held in vacuum in a hermetically sealed condition in respective quartz tubes and baked at 900° C. for seven days for a sintering reaction. Thus, As dopants of seven different types for pulling of silicon single crystal were obtained as a result of a sintering reaction.

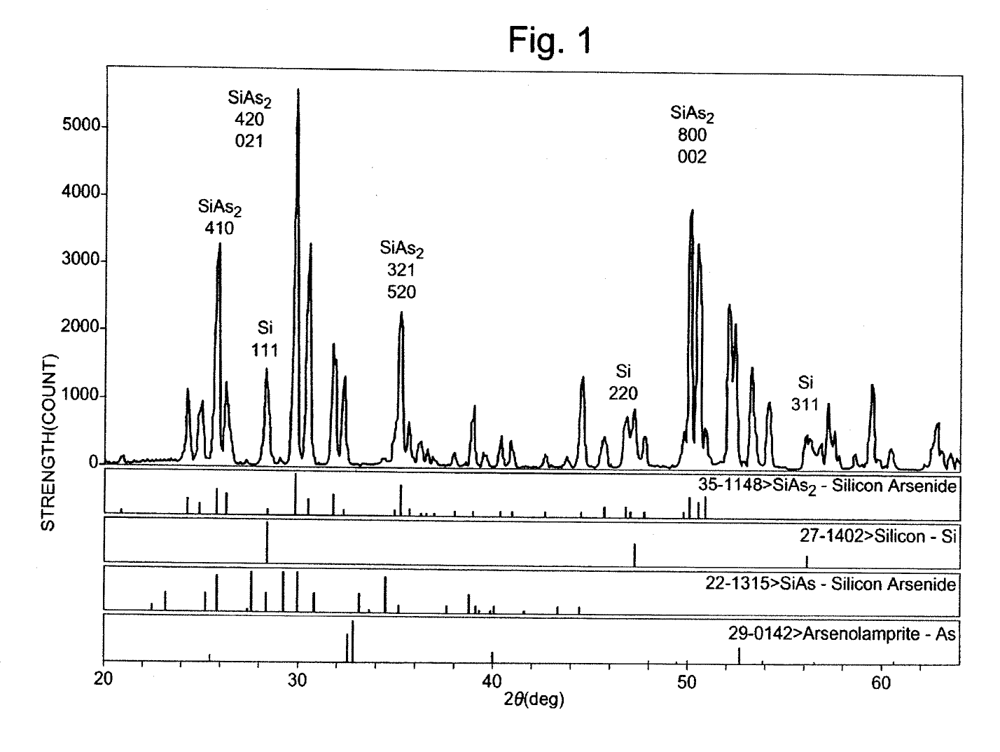

The obtained As dopant for pulling of silicon single crystal of Example 3 was observed by means of an X-ray diffractometer (XRD) to identify the produced compound. As a result, a compound of SiAs₂ and silicon, which is the sintering residue, were observed as shown in FIG. 1.

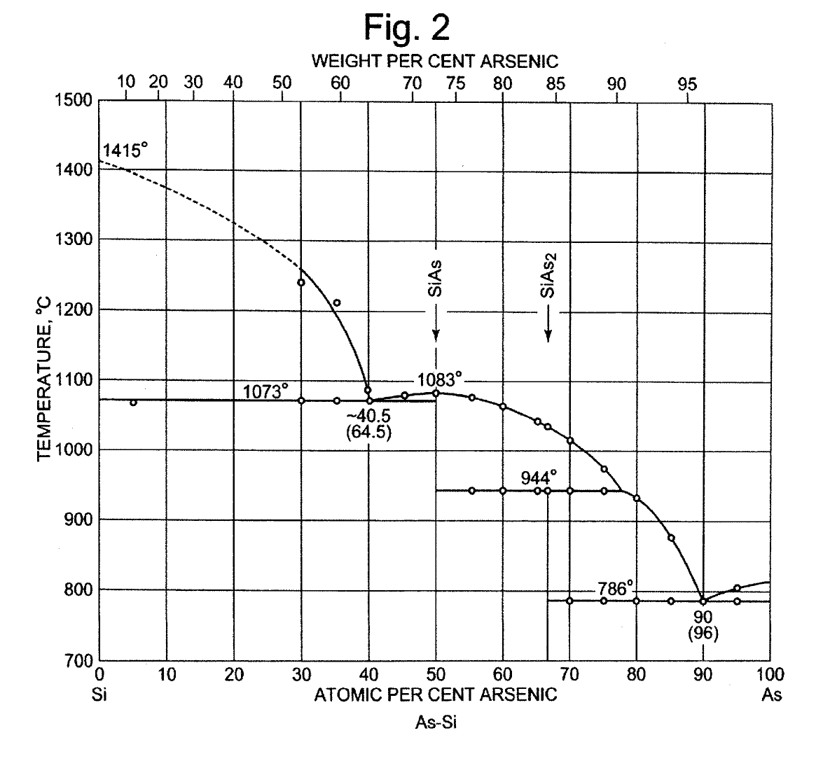

While there are two compounds of silicon arsenide including SiAs and SiAs₂, as seen from the graph in FIG. 2 (phase diagram) schematically illustrating the phases of an Si—As system, no SiAs, one of the two compounds, is contained in the As dopant for pulling of silicon single crystal of Example 3.

Silicon single crystal was made to grow by means of the Czochralski method (straight trunk section: 1 m long) under the following conditions, using each of the above described As dopants for pulling of silicon single crystal.

diameter of object to growth—silicon single crystal substrate: 150 mm

weight of raw material polysilicon; 80 kg charge

Each of the obtained silicon single crystal ingots was cut into wafers and sampled at intervals of 15 cm at the straight trunk section. Then, the resistivities (m Ω cm) of the surfaces of the sampled wafers were observed in an intra-planar radial direction by means of a four point probe resistance measuring instrument and the average value of the readings of the instrument was evaluated.

The resistivities (m Ω cm) of all the wafers produced by the cutting were observed in an intra-planar radial direction by means of a four point probe resistance measuring instrument and the yield was determined for the wafers that showed a resistivity not higher than 2.0 m Ω cm at all the measuring points in an intra-planar radial direction for a length of the straight trunk section of 1 meter.

Table 1 below shows the obtained results.

TABLE 1

| | Comp. | Comp. | Example | Example | Example | Example | Comp. |
|---|---|---|---|---|---|---|---|
| | Ex. 1 | Ex. 2 | 1 | 2 | 3 | 4 | Ex. 3 |
| molar ratio | 0 | 25 | 35 | 45 | 50 | 55 | 60 |
| (%) | | | | | | | |
| average | 4.5 | 3.3 | 2.8 | 2.3 | 2.3 | 2.7 | 3.3 |
| resistivity | | | | | | | |
| (m Ω cm) | | | | | | | |
| yield (%) | 20.0 | 27.0 | 40.5 | 62.0 | 60.0 | 43.5 | 28.0 |

As seen from Table 1, the yield of wafers with an intra-planar average resistivity of not higher than 3 m Ω cm (milliohm centimeter) and a resistivity of not greater than 2.0 m Ω cm in an intra-planar radial direction at all the measuring points when the molar ratio of silicon was within a range between 35% and 55% relative to arsenic was not lowerthan40% to evidencea significant improvement. Thus, it was proved that it is possible to produce low resistivity silicon single crystal according to the present invention.

The yield of wafers with an intra-planar average resistivity of not higher than 2.5 m Ω cm and a resistivity of not greater than 2.0 m Ω cm in an intra-planar radial direction at all the measuring points when the molar ratio was within a range between 45% and 50% relative to arsenic exceeded 60% to evidence a more significant improvement.

It goes without saying that various obvious modifications and simple variants come within the scope of the present invention beyond the above-described embodiment.

1. (cancelled)

2. (cancelled)

3. (cancelled)

4. (cancelled)

5. (cancelled)

6. (cancelled)

7. A process for producing a silicon single crystal which comprises:
a step of filling a crucible with raw material silicon, melting the silicon to form raw material silicon melt;
a step of introducing an As dopant comprising a mixed sintered compact of granular or powdery arsenic and silicon, the molar ratio of silicon being not smaller than 35% and not greater than 55% relative to arsenic, into the raw material silicon melt and melting the As dopant; and
a step of growing the silicon single crystal by allowing seed crystal of silicon single crystal to contact the raw material silicon melt containing the dissolved As dopant.

8. A process for producing a silicon single crystal which comprises:
a step of filling a crucible with raw material silicon, melting the silicon to form raw material silicon melt;
a step of introducing an As dopant comprising a mixed sintered compact of granular or powdery arsenic and silicon, the molar ratio of silicon being not smaller than 45% and not greater than 50% relative to arsenic, into the raw material silicon melt and melting the As dopant; and
a step of growing the silicon single crystal by allowing seed crystal of silicon single crystal to contact the raw material silicon melt containing the dissolved As dopant.
